(19) United States
(12) Patent Application Publication
(10) Pub. No.: US 2026/0055510 A1
(43) Pub. Date: Feb. 26, 2026

(54) FILM FORMING APPARATUS AND DETERMINATION METHOD

(71) Applicant: Tokyo Electron Limited, Tokyo (JP)

(72) Inventors: Hiroki MIURA, Iwate (JP); Masato KOAKUTSU, Iwate (JP); Yoshinori KUSAKABE, Iwate (JP)

(21) Appl. No.: 19/292,191

(22) Filed: Aug. 6, 2025

(30) Foreign Application Priority Data
Aug. 21, 2024 (JP) 2024-139414

(51) Int. Cl. C23C 16/52; C23C 16/44; G01N 21/25

(52) U.S. Cl. CPC C23C 16/52; C23C 16/4401; G01N 21/251

(57) ABSTRACT

A film forming apparatus performs a film forming process to form a film inside a vacuum chamber and a cleaning process to remove the film formed inside the vacuum chamber. The film forming apparatus includes the vacuum chamber, a member disposed inside the vacuum chamber, an acquisition device that acquires first information related to electromagnetic waves transmitted through or reflected by the member, and a control circuit configured to perform a process including determining at least one of a start timing and an end timing of the cleaning process based on the first information acquired by the acquisition device.

### CROSS-REFERENCE TO RELATED APPLICATIONS

This application is based upon and claims priority to Japanese Patent Application No. 2024-139414, filed on Aug. 21, 2024, the entire contents of which are incorporated herein by reference.

### BACKGROUND

### 1. Field of the Invention

The present disclosure relates to film forming apparatuses and determination methods for determining a start timing or an end timing of a cleaning process.

### 2. Description of the Related Art

For example, Japanese Laid-Open Patent Publication No. 2021-128977 proposes detecting an end timing of a cleaning process based on a captured image of a low-temperature surface inside a vacuum chamber.

### SUMMARY

One aspect of the present disclosure provides technique capable of improving an accuracy of determining a timing of a cleaning processing.

According to one aspect of the present disclosure, a film forming apparatus configured to perform a film forming process to form a film inside a vacuum chamber and a cleaning process to remove the film formed inside the vacuum chamber, includes the vacuum chamber; a member disposed inside the vacuum chamber; an acquisition device that acquires first information related to electromagnetic waves transmitted through or reflected by the member; and a control circuit configured to perform a process including determining at least one of a start timing and an end timing of the cleaning process based on the first information acquired by the acquisition device.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating a configuration example of a film forming apparatus according to an embodiment;

FIG. 2 is a perspective view illustrating a configuration inside a vacuum chamber of the film forming apparatus according to the embodiment;

FIG. 3 is a plan view illustrating the configuration inside the vacuum chamber of the film forming apparatus according to the embodiment;

FIG. 4 is a cross sectional view illustrating a part of the film forming apparatus according to the embodiment;

FIG. 5 is a cross sectional view illustrating another part of the film forming apparatus according to the embodiment;

FIG. 6 is a flow chart illustrating a first example of a determination method according to the embodiment;

FIG. 7 is a cross sectional view (1) for explaining the first example of the determination method according to the embodiment;

FIG. 8 is a cross sectional view (2) for explaining the first example of the determination method according to the embodiment;

FIG. 9 is a cross sectional view (3) for explaining the first example of the determination method according to the embodiment;

FIG. 10 is a cross sectional view (4) for explaining the first example of the determination method according to the embodiment;

FIG. 11 is a cross sectional view (5) for explaining the first example of the determination method according to the embodiment;

FIG. 12 is a flow chart illustrating a second example of the determination method according to the embodiment.

FIG. 13 is a flow chart illustrating a third example of the determination method according to the embodiment;

FIG. 14 is a cross sectional view (1) for explaining the third example of the determination method according to the embodiment;

FIG. 15 is a cross sectional view (2) for explaining the third example of the determination method according to the embodiment;

FIG. 16 is a cross sectional view (3) for explaining the third example of the determination method according to the embodiment;

FIG. 17 is a cross sectional view (4) for explaining the third example of the determination method according to the embodiment;

FIG. 18 is a cross sectional view (5) for explaining the third example of the determination method according to the embodiment;

FIG. 19 is a cross sectional view (6) for explaining the third example of the determination method according to the embodiment; and

FIG. 20 is a flow chart illustrating a fourth example of the determination method according to the embodiment.

### DETAILED DESCRIPTION

Hereinafter, non-limiting embodiments of the present disclosure will be described with reference to the accompanying drawings. In each of the accompanying drawings, the same or corresponding constituent elements or components are denoted by the same or corresponding reference numerals, and a redundant description thereof will be omitted.

### Film Forming Apparatus

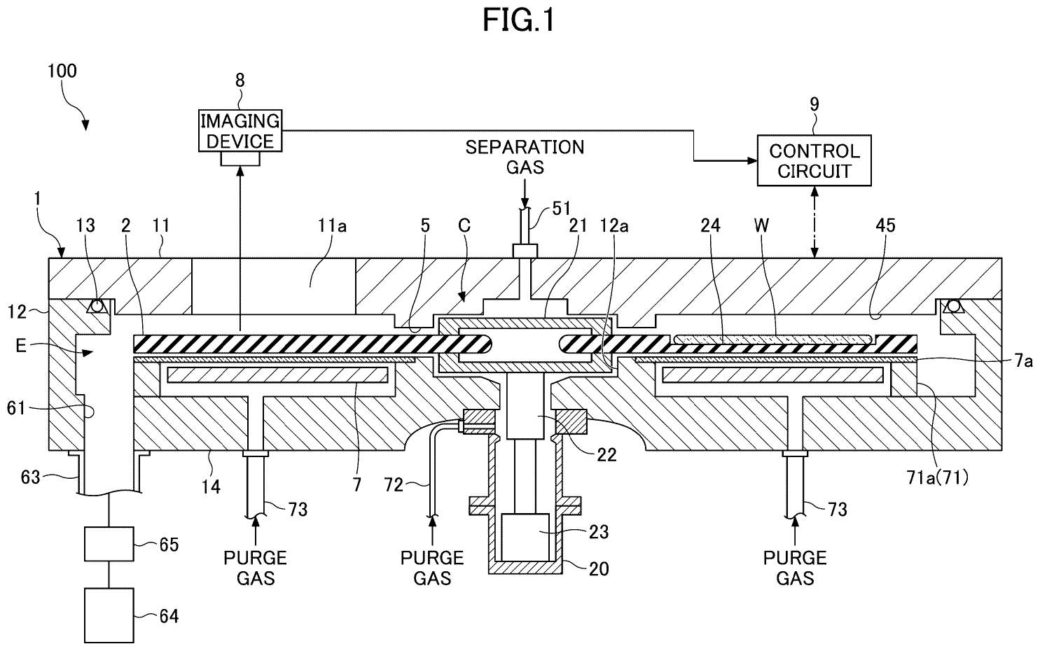

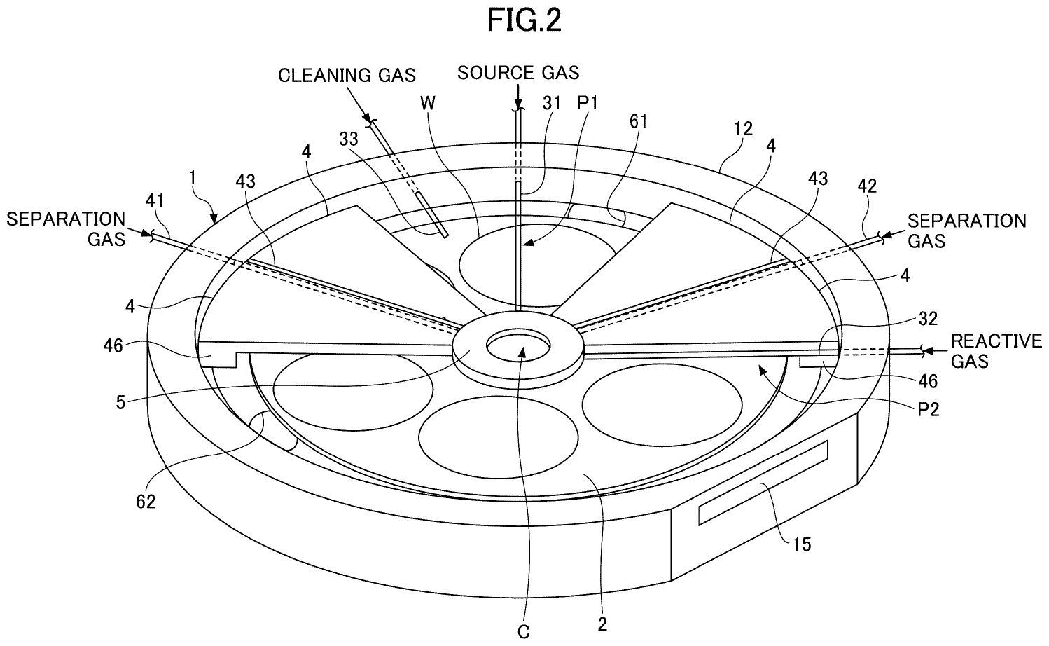

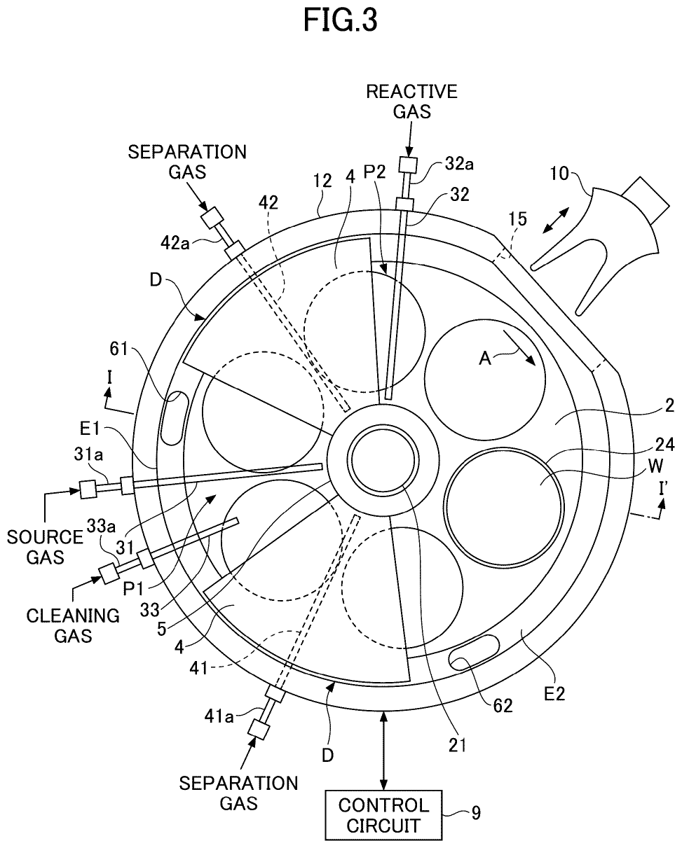

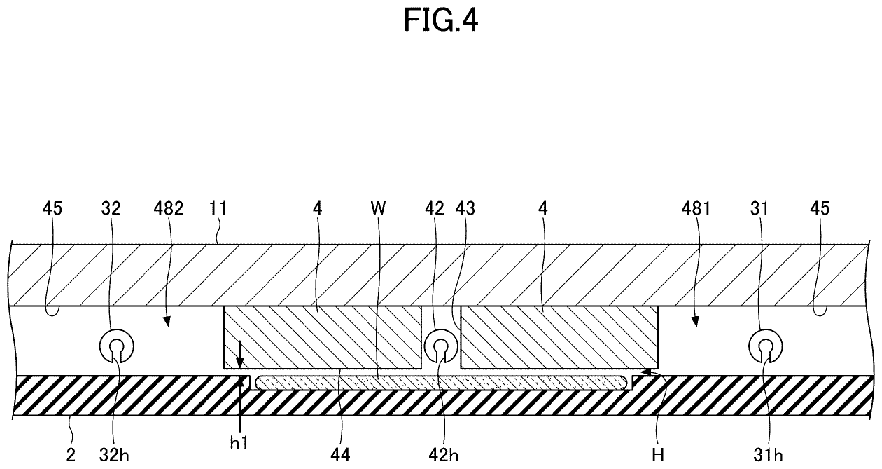

A film forming apparatus 100 according to an embodiment will be described with reference to FIG. 1 through FIG. 5. FIG. 1 is a cross sectional view illustrating a configuration example of the film forming apparatus 100 according to the embodiment. FIG. 2 is a perspective view illustrating a configuration inside a vacuum chamber 1 of the film forming apparatus 100 according to the embodiment. FIG. 3 is a plan view illustrating the configuration inside the vacuum chamber 1 of the film forming apparatus 100 according to the embodiment. In FIG. 2 and FIG. 3, the illustration of a top plate 11 will be omitted. FIG. 4 is a cross sectional view illustrating a part of the film forming apparatus 100 according to the embodiment. FIG. 5 is a cross sectional view illustrating another part of the film forming apparatus 100 according to the embodiment.

As illustrated in FIG. 1 through FIG. 3, the film forming apparatus 100 includes the vacuum chamber 1 and a susceptor 2.

The vacuum chamber 1 has an approximately circular planar shape, that is, an approximately circular shape in the plan view. The vacuum chamber 1 includes a top plate 11 and a chamber body 12. The top plate 11 is detachably provided on an upper surface of the chamber body 12 via a seal member 13, such as an O-ring or the like, in an airtight manner. A window 11a is provided in a portion of the top plate 11. The window 11a is formed of quartz, for example. The window 11a is configured to enable the susceptor 2 inside the vacuum chamber 1 to be visually recognized from an outside of the vacuum chamber 1. The chamber body 12 has a bottomed cylindrical shape.

The susceptor 2 is provided inside the vacuum chamber 1. The susceptor 2 has a center of rotation center located at a center of the vacuum chamber 1. The susceptor 2 is formed of quartz, for example. The susceptor 2 has a central portion fixed to a cylindrical core portion 21. The core portion 21 is fixed to an upper end of a rotating shaft 22. The rotating shaft 22 extends in a vertical direction. The rotating shaft 22 penetrates the bottom portion 14 of the vacuum chamber 1. A lower end of the rotating shaft 22 is attached to a drive system 23. The drive system 23 rotates the rotating shaft 22 around a vertical axis. The rotating shaft 22 and the drive system 23 are accommodated inside a casing 20. The casing 20 has a cylindrical shape with an open upper surface. A flange portion provided at the upper surface of the casing 20 is airtightly attached to a lower surface of the bottom portion 14 of the vacuum chamber 1. Hence, an airtight state is maintained between an internal atmosphere and an external atmosphere of the casing 20.

A plurality of (for example, six) recesses 24 is formed in an upper surface of the susceptor 2 along a direction of rotation (circumferential direction). Each recess 24 has a circular shape. A substrate W is placed in each recess 24. The substrate W is a semiconductor wafer, for example. In FIG. 3, the substrate W is illustrated in only one recess 24 for the sake of convenience. The recesses 24 are provided at positions displaced horizontally with respect to the rotating shaft 22 of the susceptor 2. Each recess 24 has an inside diameter slightly larger, that is, 4 mm larger than a diameter of the substrate W, for example. Further, each recess 24 has a depth approximately equal to a thickness of the substrate W. For this reason, when the substrate W is accommodated inside the recess 24, an upper surface of the substrate W and an upper surface of the susceptor 2 (an area of the susceptor 2 where the substrate W is not placed) are located at the same height. A plurality of through holes (not illustrated) is provided in a bottom surface of the recess 24. A plurality of (for example, three) raising and lowering pins for raising and lowering the substrate W while supporting a back surface of the substrate W penetrates the plurality of through holes, respectively.

Process gas nozzles 31 and 32, a cleaning gas nozzle 33, and separation gas nozzles 41 and 42 are arranged above the susceptor 2 at intervals along the circumferential direction of the vacuum chamber 1 (the direction of rotation of the susceptor 2 indicated by an arrow A in FIG. 3). In the illustrated example, the separation gas nozzle 41, the cleaning gas nozzle 33, the process gas nozzle 31, the separation gas nozzle 42, and the process gas nozzle 32 are arranged in this order in a clockwise direction (the direction of rotation of the susceptor 2) from a transfer port 15 which will be described later. Gas inlet ports 31a, 32a, 33a, 41a, 42a illustrated in FIG. 3, which are provided at base ends of the process gas nozzles 31 and 32, the cleaning gas nozzle 33, and the separation gas nozzles 41 and 42, are fixed to an outer peripheral surface of the chamber body 12. The process gas nozzles 31 and 32, the cleaning gas nozzle 33, and the separation gas nozzles 41 and 42 enter inside the vacuum chamber 1 from the outer peripheral surface of the chamber body 12, and are installed to extend horizontally with respect to the susceptor 2 along a radial direction of the chamber body 12. The process gas nozzles 31 and 32, the cleaning gas nozzle 33, and the separation gas nozzles 41 and 42 are formed of quartz, for example.

The process gas nozzle 31 is connected to a source gas supply source (not illustrated) via a pipe, a flow rate controller, or the like (not illustrated). A source gas (or a feed gas) is a silicon-containing gas, for example. The source gas may be a metal-containing gas.

The process gas nozzle 32 is connected to a reactive gas supply source (not illustrated) via a pipe, a flow rate controller, or the like (not illustrated). A reactive gas is a gas that reacts with the source gas to generate a reaction product. The reactive gas is an oxidizing gas, for example. The reactive gas may be a nitriding gas.

The cleaning gas nozzle 33 is connected to a cleaning gas supply source (not illustrated) via a pipe, a flow rate controller, or the like (not illustrated). A cleaning gas is a gas capable of removing the reaction product generated by the reaction between the source gas and the reactive gas. The cleaning gas is selected according to the types of the source gas and the reactive gas used. The cleaning gas may be a halogen-containing gas. The cleaning gas may be a fluorine-containing gas, such as chlorine trifluoride (ClF₃), nitrogen trifluoride (NF₃), or the like, for example. The cleaning gas may be a chlorine-containing gas, a bromine-containing gas, or an iodine-containing gas.

The separation gas nozzles 41 and 42 are connected to a separation gas supply source (not illustrated) via a pipe, a flow rate control valve, or the like (not illustrated). A separation gas may be an inert gas. The separation gas is argon (Ar) gas, for example. The separation gas may be nitrogen (N₂) gas.

The process gas nozzles 31 and 32 include a plurality of discharge holes 31h and 32h illustrated in FIG. 4 that opens toward the susceptor 2, respectively. The discharge holes 31h and 32h are arranged along longitudinal directions of the process gas nozzles 31 and 32, respectively, at intervals of 10 mm, for example. A region below the process gas nozzle 31 serves as an adsorption region P1 for adsorbing the source gas onto the substrate W. A region below the process gas nozzle 32 serves as a reactive region P2 where the source gas adsorbed on the substrate W in the adsorption region P1 reacts with the reactive gas.

As illustrated in FIG. 2 and FIG. 3, two projecting parts 4 are provided inside the vacuum chamber 1. The projecting parts 4 constitute separation regions D together with the separation gas nozzles 41 and 42, respectively. For this reason, as will be described later, the projecting parts 4 are attached to a back surface of the top plate 11 so as to project toward the susceptor 2. The projecting parts 4 have a fan-like planar shape with a top portion cut in an arcuate shape. Each projecting part 4 is disposed such that an inner arc thereof is connected to a protrusion 5 which will be described later, and an outer arc thereof extends along an inner peripheral surface of the chamber body 12 of the vacuum chamber 1, that is, along an inner peripheral wall of the vacuum chamber 1.

FIG. 4 illustrates a cross section of the vacuum chamber 1 along concentric circles of the susceptor 2 from the process gas nozzle 31 to the process gas nozzle 32. As illustrated in FIG. 4, the projecting part 4 is attached to the back surface of the top plate 11. For this reason, a flat low ceiling surface (a first ceiling surface 44) which is a lower surface of the projecting part 4, and ceiling surfaces (second ceiling surfaces 45) which are positioned on both sides of the first ceiling surface 44 in the circumferential direction and are higher than the first ceiling surface 44, are provided inside the vacuum chamber 1. The first ceiling surface 44 has a fan-like planar shape with a top portion cut in an arcuate shape. The projecting part 4 is formed with a groove 43 formed to extend in the radial direction from a middle in the circumferential direction. The separation gas nozzle 42 is accommodated inside the groove 43. Similarly, another groove 43 is formed in the other projecting part 4, and the separation gas nozzle 41 is accommodated inside this other groove 43. The process gas nozzles 31 and 32 are provided in the spaces below the second ceiling surfaces 45, respectively. The process gas nozzles 31 and 32 are provided at positions near the substrate W but separated from the second ceiling surfaces 45. As illustrated in FIG. 4, the process gas nozzle 31 is provided in a space 481 below the second ceiling surface 45 on the right side of the projecting part 4, and the process gas nozzle 32 is provided in a space 482 below the second ceiling surface 45 on the left side of the projecting part 4.

The separation gas nozzle 42 includes a plurality of discharge holes 42h that opens toward the susceptor 2. The plurality of discharge holes 42h is arranged along a longitudinal direction of the separation gas nozzle 42 at intervals of 10 mm, for example. The separation gas nozzle 41 includes a plurality of discharge holes (not illustrated), similar to the separation gas nozzle 42.

The first ceiling surface 44 forms a separation space H, which is a narrow space, with respect to the susceptor 2. When the separation gas is supplied from the plurality of discharge holes 42h of the separation gas nozzle 42, the separation gas flows toward the spaces 481 and 482 through the separation space H. In this state, because a volume of the separation space H is smaller than volumes of the spaces 481 and 482, the separation gas can make a pressure at the separation space H higher than pressures at the spaces 481 and 482. That is, the separation space H having a high pressure can be formed between the spaces 481 and 482. The separation gas flowing out from the separation space H to the spaces 481 and 482 serves as a counter flow with respect to the source gas from the adsorption region P1 and the reactive gas from the reactive region P2. For this reason, the source gas supplied to the adsorption region P1 and the reactive gas supplied to the reactive region P2 are separated by the separation space H. Accordingly, it is possible to reduce the reaction between the source gas and the reactive gas caused by the mixing of the source gas and the reactive gas inside the vacuum chamber 1.

A height h1 of the first ceiling surface 44 with respect to the upper surface of the susceptor 2 is set to a height suitable for making the pressure at the separation space H higher than the pressures at the spaces 481 and 482, by taking into consideration the pressure inside the vacuum chamber 1 during film formation, a rotation speed of the susceptor 2, a flow rate of the separation gas, or the like.

The protrusion 5 surrounding the outer periphery of the core portion 21 for fixing the susceptor 2 is provided on the lower surface of the top plate 11. The protrusion 5 is continuous with portions of the projecting parts 4 on the side of the center of rotation, and a lower surface of the protrusion 5 is formed to the same height as the first ceiling surface 44.

FIG. 1 described above is a cross sectional view taken along a line I-I′ in FIG. 3, and illustrates regions where the second ceiling surfaces 45 are provided. On the other hand, FIG. 5 illustrates a region where the first ceiling surface 44 is provided. As illustrated in FIG. 5, a bent portion 46 that is bent in an L-shape is formed at a peripheral edge of the fan-shaped projecting part 4 (a portion on an outer edge of the vacuum chamber 1) so as to oppose an outer end surface of the susceptor 2. The bent portion 46 reduces the intrusion of the source gas and the reactive gas from both sides of a separation region D and reduces the mixing of the source gas and the reactive gas, similar to the projecting part 4. The projecting part 4 is provided on the top plate 11, and the top plate 11 is detachable from the chamber body 12. Hence, there is a slight gap between an outer peripheral surface of the bent portion 46 and the chamber body 12. A gap between an inner peripheral surface of the bent portion 46 and the outer end surface of the susceptor 2, and the gap between the outer peripheral surface of the bent portion 46 and the chamber body 12, are set to have the same size as the height of the first ceiling surface 44 with respect to the upper surface of the susceptor 2, for example.

The inner peripheral surface of the chamber body 12 is formed as a vertical surface in the separation region D near the outer peripheral surface of the bent portion 46 illustrated in FIG. 5, but is recessed outward from a portion opposing the outer end surface of the susceptor 2 to the bottom portion 14 in a region other than the separation region D illustrated in FIG. 1. Hereinafter, for the sake of convenience, the recessed portion of the inner peripheral surface of the chamber body 12 having an approximately rectangular cross sectional shape will be referred to as an exhaust region E. More particularly, the exhaust region E communicating with the adsorption region P1 will be referred to as a first exhaust region E1, and the exhaust region E communicating with the reactive region P2 will be referred to as a second exhaust region E2. As illustrated in FIG. 1 through FIG. 3, a first exhaust port 61 and a second exhaust port 62 are formed in the bottom portions of the first exhaust region E1 and the second exhaust region E2, respectively. As illustrated in FIG. 1, the first exhaust port 61 and the second exhaust port 62 are connected to a vacuum pump 64 which is a vacuum exhaust unit, for example, via exhaust pipes 63, respectively. A pressure controller (or a pressure regulator) 65 is provided in the exhaust pipe 63, and is configured to be able to adjust the pressure inside the vacuum chamber 1.

As illustrated in FIG. 1 and FIG. 5, a heater 7 is provided in an installation space between the susceptor 2 and the bottom portion 14 of the vacuum chamber 1. The heater 7 heats the substrate W on the susceptor 2 to a temperature determined by a process recipe by radiation.

An annular cover member 71 is provided below the susceptor 2 near the peripheral edge thereof, as illustrated in FIG. 5. The cover member 71 separates an atmosphere from the upper space of the susceptor 2 to the first exhaust region E1 and the second exhaust region E2 from an atmosphere in which the heater 7 is provided, thereby reducing the intrusion of gases into the lower region of the susceptor 2. The cover member 71 has an inner member 71a and an outer member 71b. The inner member 71a is provided to oppose the outer edge of the susceptor 2 and the outer peripheral side of the outer edge from below. The inner member 71a surrounds an entire periphery of the heater 7 below the outer edge of the susceptor 2 (below a portion slightly on the outer side than the outer edge). The outer member 71b is provided between the inner member 71a and the inner peripheral wall of the vacuum chamber 1. The outer member 71b is provided near the bent portion 46, below the bent portion 46 formed on the outer edge of the projecting part 4 in the separation region D.

The bottom portion 14, at a portion closer to the center of rotation than the installation space for the heater 7, protrudes upward to approach the core portion 21 near the central portion of the lower surface of the susceptor 2, thereby forming a protrusion 12a. A narrow space is formed between the protrusion 12a and the core portion 21, and a narrow space is formed between an inner peripheral surface of the through hole of the rotating shaft 22 penetrating the bottom portion 14 and the rotating shaft 22. These narrow spaces communicate with the casing 20. A purge gas supply pipe 72 is provided in the casing 20. The purge gas supply pipe 72 supplies a purge gas into the narrow spaces to purge the narrow spaces. The purge gas is the same gas as the separation gas, for example. A plurality of purge gas supply pipes 73 is provided in the bottom portion 14 of the vacuum chamber 1. The plurality of purge gas supply pipes 73 is provided at predetermined angular intervals in the circumferential direction below the heater 7. The plurality of purge gas supply pipes 73 supplies the purge gas to the installation space for the heater 7, to purge the installation space. A lid member 7a is provided between the heater 7 and the susceptor 2. The lid member 7a covers a space between an inner peripheral wall of the outer member 71b (the upper surface of the inner member 71a) and the upper end of the protrusion 12a in the circumferential direction. Accordingly, it is possible to reduce the intrusion of gases into the installation region for the heater 7. The lid member 7a is formed of quartz, for example.

A separation gas supply pipe 51 is connected to a center of the top plate 11 of the vacuum chamber 1. The separation gas supply pipe 51 supplies a separation gas to a space 52 between the top plate 11 and the core portion 21. The separation gas supplied to the space 52 is discharged toward the peripheral edge along the surface of the susceptor 2 on the side of the wafer placing region through a narrow gap 50 between the protrusion 5 and the susceptor 2. The gap 50 can be maintained at a pressure higher than the pressures at the spaces 481 and 482 by the separation gas. The gap 50 reduces mixing of the source gas supplied to the adsorption region P1 and the reactive gas supplied to the reactive region P2 through a central region C. That is, the gap 50 (or the central region C) functions similarly to the separation space H (or the separation region D).

As illustrated in FIG. 2 and FIG. 3, the transfer port 15 for transferring the substrate W between an external transfer arm 10 and the susceptor 2 is provided in a sidewall of the vacuum chamber 1. The transfer port 15 is opened and closed by a gate valve (not illustrated). The raising and lowering pins (not illustrated), which penetrate the through holes in the bottom surface of the recess 24, raise the substrate W to a position corresponding to a substrate transport position by supporting the back surface of the substrate W, using an elevator mechanism (not illustrated). The raising and lowering pins and the elevator mechanism are provided below the susceptor 2.

The film forming apparatus 100 includes an imaging device 8. The imaging device 8 is provided above the window 11a. The imaging device 8 is capable of capturing an image of the upper surface of the susceptor 2 through the window 11a. The imaging device 8 may include a camera, and generate an image by the camera. In the example illustrated in FIG. 1, only one imaging device 8 is provided, but two or more imaging devices 8 may be provided, as appropriate. The imaging device 8 is an example of an acquisition device.

The imaging device 8 captures the image of the upper surface of the susceptor 2 before forming a film, and acquires the image of the upper surface of the susceptor 2 before forming the film (hereinafter also referred to as “a comparative image”). The imaging device 8 transmits the acquired comparative image to a control circuit 9. The comparative image is an example of first information. The susceptor 2 before a film 101 is formed thereon is a new susceptor 2 in an unused state, for example. The susceptor 2 before forming the film 101 may be a susceptor 2 in a state where the film on the upper surface thereof is removed by a cleaning process.

The imaging device 8 captures the image of the upper surface of the susceptor 2 after forming the film, and acquires the image of the upper surface of the susceptor 2 after performing the film forming process (hereinafter also referred to as “a first determination image”). The imaging device 8 transmits the acquired first determination image to the control circuit 9. The first determination image is an example of the first information. The imaging device 8 may acquire the first determination image while performing the film forming process.

The imaging device 8 captures the image of the upper surface of the susceptor 2 during the cleaning process, and acquires the image of the upper surface of the susceptor 2 during the cleaning process (hereinafter also referred to as “a second determination image”). The imaging device 8 transmits the acquired second determination image to the control circuit 9. The second determination image is an example of the first information.

The film forming apparatus 100 includes the control circuit 9. The control circuit 9 is electronic circuitry, such as a central processing unit (CPU), a field programmable gate array (FPGA), an application specific integrated circuit (ASIC), or the like. The control circuit 9 performs various control operations described in the present specification by executing instruction codes stored in a memory. Alternatively, the control circuit may be designed for specialized applications or may be circuit designed for special-purpose use.

The control circuit 9 controls various parts or components of the film forming apparatus 100 to perform the film forming process and the cleaning process. The film forming process includes forming a film on the substrate W placed on the susceptor 2 (in the recess 24) inside the vacuum chamber 1, for example. During the film forming process, the film is formed not only on the surface of the substrate W but also on the susceptor 2. The susceptor 2 is an example of a member disposed inside the vacuum chamber 1. When a thickness of the film formed on the susceptor 2 increases, a film delamination from the susceptor 2 occurs, thereby generating particles. The particles adhere to the surface of the substrate W during the film forming process and contaminate the substrate W. The cleaning process includes removing a film formed on the susceptor 2 during the film forming process, for example. The cleaning process is performed periodically, for example. The cleaning process is performed before the film delamination from the susceptor 2 occurs, for example. Thus, the film formed on the susceptor 2 is removed before the film delamination occurs, and the generation of the particles can be prevented.

The cleaning process is performed by supplying the cleaning gas into the vacuum chamber 1 for a predetermined time. The predetermined time varies when the operation of the film forming apparatus 100 modified or the like. If a duration of the cleaning process is too short, the film remains on the susceptor 2, and particles are likely generated during a next film forming process. On the other hand, if the duration of the cleaning process is excessively long, the susceptor 2 may become etched, resulting in a decrease in strength or a decrease in serviceable life of the susceptor 2. For this reason, it is important to end the cleaning process at an appropriate timing.

The control circuit 9 determines an end timing of the cleaning process, based on the second determination image and the comparative image acquired by the imaging device 8. For example, the control circuit 9 calculates a difference between the color information at a predetermined position of the second determination image and color information at a predetermined position of the comparative image, and determines the end timing of the cleaning process based on the calculated difference. The predetermined position of the comparative image is the same as the predetermined position of the second determination image, for example. The color information includes red, green, and blue (RGB) values, for example. The control circuit 9 may calculate a difference between intensities of at least one of the three primary colors of red, green, and blue constituting the RGB values of the second determination image and the comparative image, and determine the end timing of the cleaning process based on the calculated difference. The color information may be hue, saturation, and lightness (HSL) values. The control circuit 9 controls the operations of the various parts or components of the film forming apparatus 100 so as to end the cleaning process at the determined end timing. As a result, it is possible to improve an accuracy of determining the end timing of the cleaning process.

For example, in a case where the susceptor 2 is formed of quartz and the film formed by the film forming process is a silicon film, suppose that the intensities of blue constituting the RGB values at the predetermined positions of the second determination image and the comparative image are 30 and 150, respectively. In this case, the control circuit 9 calculates a value of the difference by subtracting the intensity of blue at the predetermined position of the comparative image from the intensity of blue at the predetermined position of the second determination image. The calculated value of the difference in this case is −120. The intensity of blue at the predetermined position of the second determination image increases as the thickness of the silicon film decreases. When the silicon film is completely removed, the intensity of blue at the predetermined position of the second determination image becomes equal to the intensity of blue at the predetermined position of the comparative image or becomes larger than the intensity of blue at the predetermined position of the comparative image. Hence, the control circuit 9 determines to end the cleaning process when the calculated value of the difference is greater than or equal to 0, thereby minimizing under-etching or over-etching.

The control circuit 9 may determine a start timing of the cleaning process based on the first determination image and the comparative image acquired by the imaging device 8. For example, the control circuit 9 calculates a value of the difference between color information at the predetermined position of the first determination image and color information at the predetermined position of the comparative image, and determines the start timing of the cleaning process based on the calculated value of the difference. The predetermined position of the comparative image is the same as the predetermined position of the first determination image, for example. The color information includes red, green, and blue (RGB) values, for example. The control circuit 9 may calculate a difference between intensities of at least one of the three primary colors of red, green, and blue constituting the RGB values of the first determination image and the comparative image, and determine the start timing of the cleaning process based on the calculated difference. The color information may be a hue, saturation, and lightness (HSL) values. The control circuit 9 controls the operations of the various parts or components of the film forming apparatus 100 so as to start the cleaning process at the determined start timing. As a result, it is possible to improve an accuracy of determining the start timing of the cleaning process.

### Determination Method

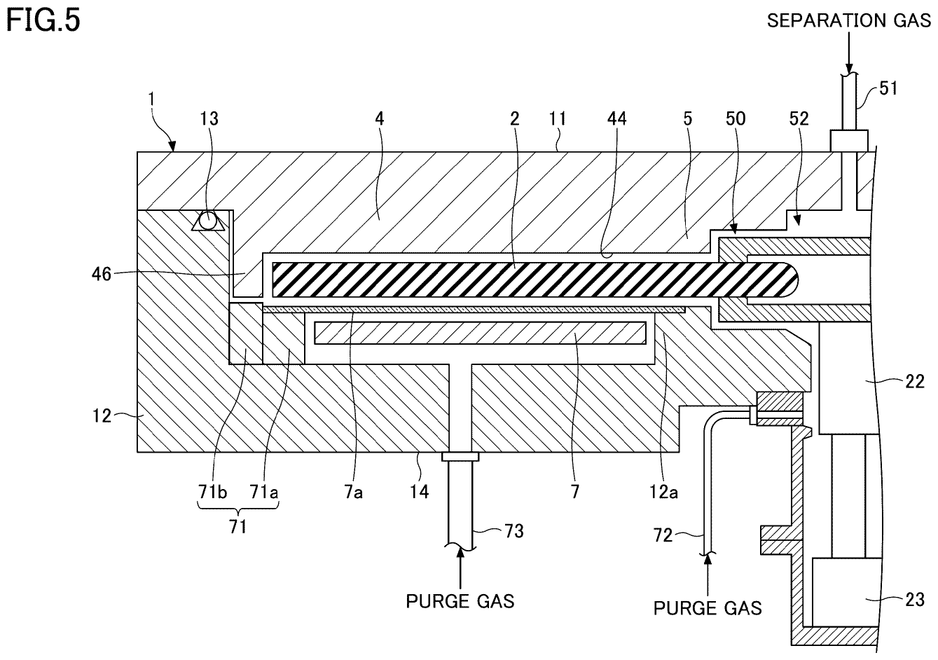

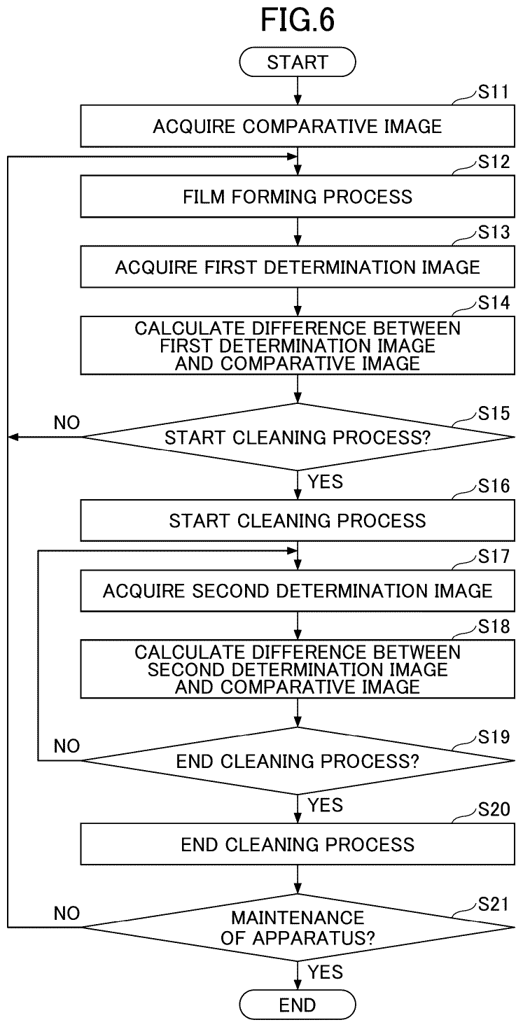

A determination method according to a first example of the embodiment will be described with reference to FIG. 6 through FIG. 11. The determination method according to the first example of the embodiment determines a start timing and an end timing of the cleaning process in a case where the film formed on the substrate W during the film forming process is a colored film. The colored film is a silicon film, a silicon nitride film, a high dielectric constant (high-k) film, or a titanium nitride film, for example. The determination method according to the first example of the embodiment is performed under the control of the control circuit 9.

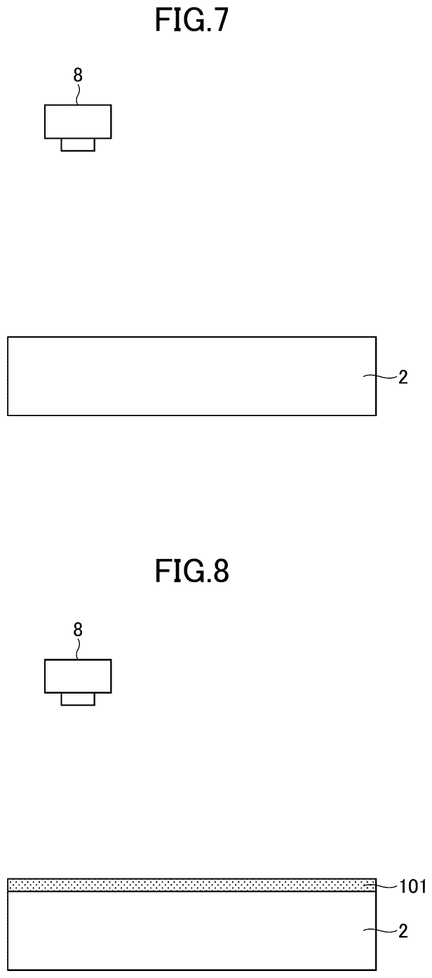

FIG. 6 is a flow chart illustrating the determination method according to the first example of the embodiment. FIG. 7 through FIG. 11 are cross sectional views for explaining the determination method according to the first example of the embodiment. The determination method illustrated in FIG. 6 includes steps S11 through S21.

In step S11, as illustrated in FIG. 7, the imaging device 8 captures the image of the upper surface of the susceptor 2 before forming the film 101 thereon, and acquires the comparative image of the susceptor 2. The imaging device 8 transmits the acquired comparative image to the control circuit 9.

In step S12, the control circuit 9 controls the various parts or components of the film forming apparatus 100 to perform the film forming process. The film forming process is performed in a state where the substrate W is placed on the susceptor 2. When the film forming process is performed, the film 101 is formed on the upper surface of the susceptor 2 as illustrated in FIG. 8.

In step S13, as illustrated in FIG. 8, the imaging device 8 captures the image the upper surface of the susceptor 2 after the film forming process is performed, and acquires the first determination image of the susceptor 2. The imaging device 8 transmits the acquired first determination image to the control circuit 9. In step S13, the imaging device 8 may acquire the first determination image while performing the film forming process of step S12.

In step S14, the control circuit 9 calculates the difference between the color information at predetermined position of the first determination image and the color information at the predetermined positions of the comparative image. The difference becomes larger as the thickness of the film 101 formed on the upper surface of the susceptor 2 becomes larger.

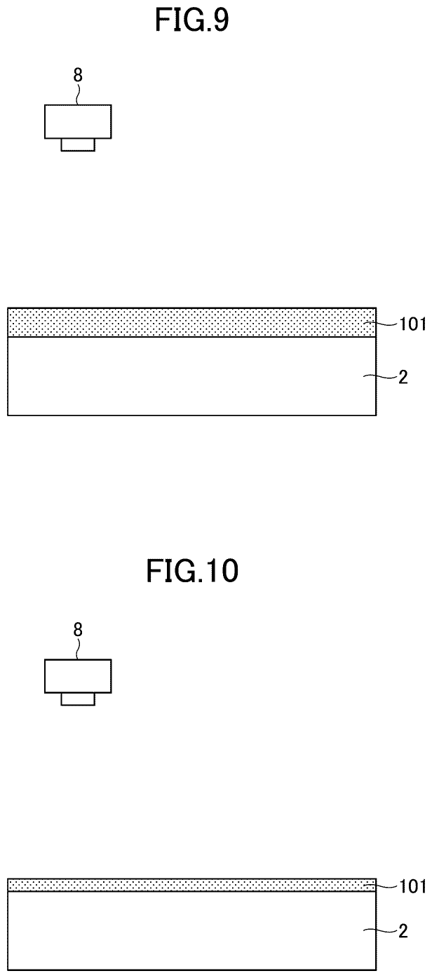

In step S15, the control circuit 9 determines whether or not to start the cleaning process based on the calculated difference. For example, the control circuit 9 determines to start the cleaning process when an absolute value of the calculated difference exceeds a preset threshold value. The threshold value is set according to a preliminary experiment or the like, so that the film delamination from the susceptor 2 is unlikely to occur. In a case where it is determined in step S15 that the cleaning process is to be started (YES in step S15), the control circuit 9 advances the process to step S16. On the other hand, in a case where it is determined in step S15 that the cleaning process is not to be started (NO in step S15), the control circuit 9 returns the process to step S12. That is, the control circuit 9 controls the various parts or components of the film forming apparatus 100 so as to repeatedly perform the film forming process without performing the cleaning process until step S15 determines that the cleaning process is to be started. When the film forming process is repeatedly performed, as illustrated in FIG. 9, the thickness of the film 101 formed on the upper surface of the susceptor 2 increases.

In step S16, the control circuit 9 controls the various parts or components of the film forming apparatus 100 to start the cleaning process. When the cleaning process is started, the thickness of the film 101 formed on the upper surface of the susceptor 2 gradually decreases, as illustrated in FIG. 10.

In step S17, the imaging device 8 captures the image of the upper surface of the susceptor 2 while performing the cleaning process, and acquires the second determination image of the susceptor 2. The imaging device 8 transmits the acquired second determination image to the control circuit 9.

In step S18, the control circuit 9 calculates the difference between the color information at the predetermined position of the second determination image and the color information at the predetermined position of the comparative image. The difference becomes smaller as the thickness of the film 101 formed on the upper surface of the susceptor 2 decreases.

In step S19, the control circuit 9 determines whether or not to end the cleaning process based on the calculated difference. For example, when the absolute value of the calculated difference becomes less than or equal to a preset threshold value, the control circuit 9 determines that the film 101 is removed and determines to end the cleaning process. The threshold value is 0 (zero), for example. When it is determined in step S19 that the cleaning process is to be ended (YES in step S19), the control circuit 9 advances the process to step S20. On the other hand, it is determined in step S19 that the cleaning process is not to be ended (NO in step S19), the control circuit 9 returns the process to step S17. That is, the control circuit 9 controls the various parts or components of the film forming apparatus 100 so as to continue the cleaning process until step S19 determines that the cleaning process is to be ended.

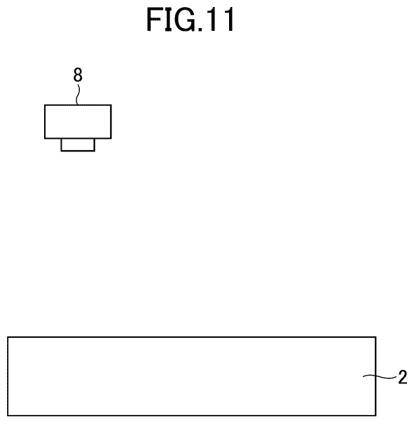

In step S20, the control circuit 9 controls the various parts or components of the film forming apparatus 100 to end the cleaning process. Thus, as illustrated in FIG. 11, the film 101 formed on the upper surface of the susceptor 2 is removed.

In step S21, the control circuit 9 determines whether or not to attend to maintenance of the film forming apparatus 100. Whether or not to attend to the maintenance is determined based on the number of cycles, duration, or the like of the cleaning process performed (or the number of cleaning cycles, cleaning duration, or the like), with reference to a point in time when the susceptor 2 is replaced, for example. When it is determined in step S21 that the maintenance is to be performed (YES in step S21), the control circuit 9 ends the process illustrated in FIG. 6. On the other hand, when it is determined in step S21 that the maintenance is not to be performed (NO in step S21), the control circuit 9 returns the process to step S12.

As described above, according to the determination method of the first example of the embodiment, the control circuit 9 calculates the difference between the color information at the predetermined position of the first determination image and the color information at the predetermined position of the comparative image, and determines the start timing of the cleaning process based on the calculated difference. In this case, it is possible to improve the accuracy of determining the start timing of the cleaning process. The control circuit 9 calculates the difference between the color information at the predetermined position of the second determination image and the color information at the predetermined position of the comparative image, and determines the end timing of the cleaning process based on the calculated difference. In this case, it is possible to improve the accuracy of determining the end timing of the cleaning process.

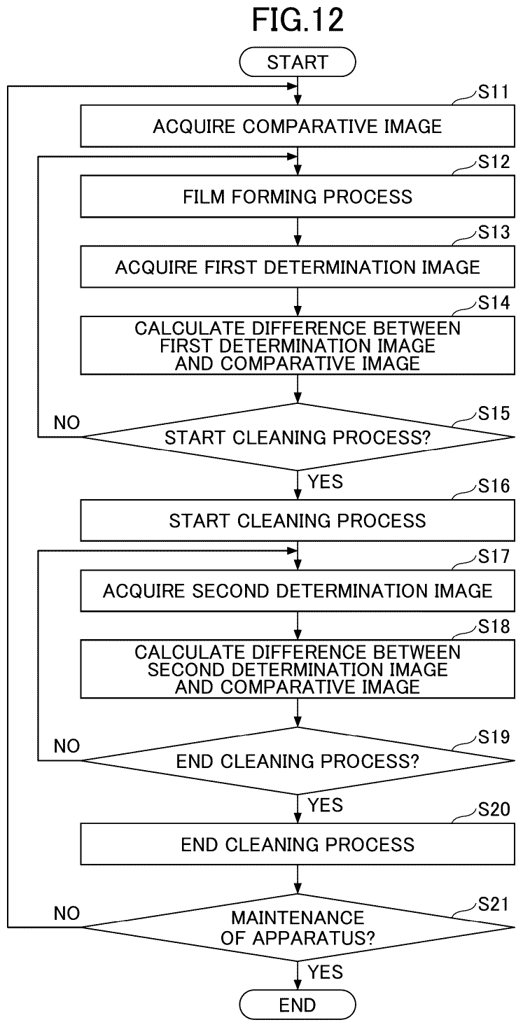

The determination method according to a second example of the embodiment will be described with reference to FIG. 12. The determination method according to the second example of the embodiment differs from the determination method according to the first example of the embodiment in that the imaging device 8 newly acquires a comparative image every time the cleaning process is performed. Otherwise, the determination method according to the second example of the embodiment may be the same as the determination method according to the first example of the embodiment. FIG. 12 is a flow chart illustrating the determination method according to the second example of the embodiment.

As illustrated in FIG. 12, in the determination method according to the second example of the embodiment, when it is determined in step S21 that the maintenance of the film forming apparatus 100 is not to be performed (NO in step S21), the control circuit 9 returns the process to step S11. That is, the imaging device 8 newly acquires a comparative image, and the control circuit 9 determines whether or not to end the cleaning process based on the difference between the color information of the second determination image and the color information of the comparative image newly received from the imaging device 8. In this case, even in a case where the surface state of the susceptor 2 varies due to the cleaning process, the newest comparative image can be used, so that the end timing of the cleaning process can be determined with a high accuracy.

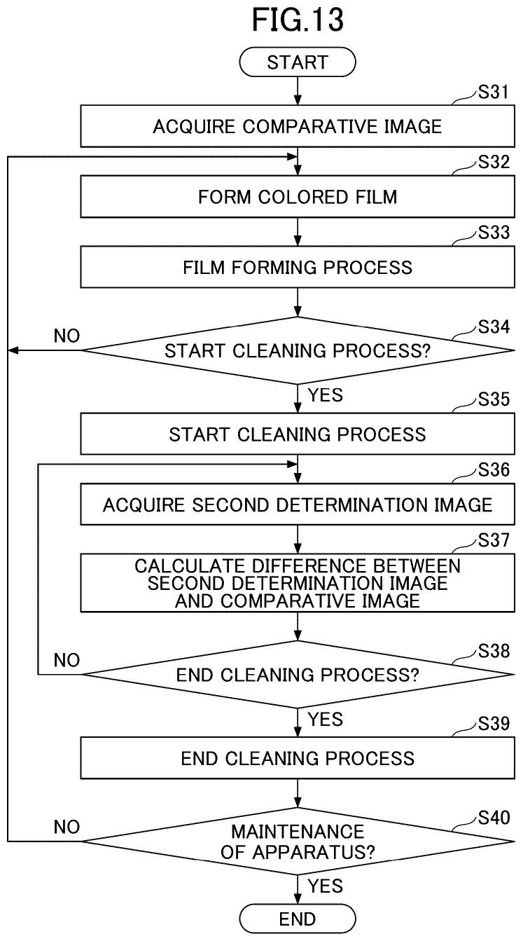

The determination method according to a third example of the embodiment will be described with reference to FIG. 13 through FIG. 19. The determination method according to the third example of the embodiment determines the start timing and the end timing of the cleaning process in a case where the film formed on the substrate W during the film forming process is a transparent film or a white film. The transparent film is a silicon oxide film, for example. The determination method according to the third example of the embodiment is performed under the control of the control circuit 9.

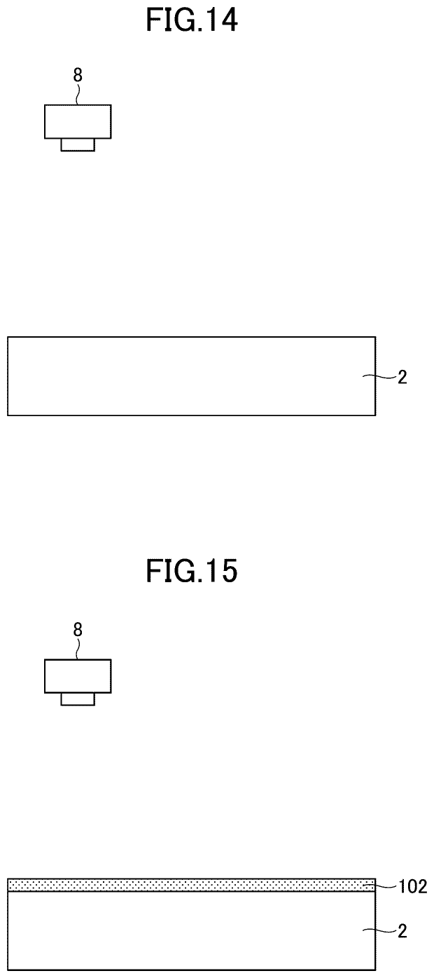

FIG. 13 is a flow chart illustrating a determination method according to the third example of the embodiment. FIG. 14 through FIG. 19 are cross sectional views for explaining the determination method according to the third example of the embodiment. The determination method illustrated in FIG. 13 includes steps S31 through S40.

In step S31, as illustrated in FIG. 14, the imaging device 8 captures the image the upper surface of the susceptor 2 before the film 101 is formed thereon, and acquires the comparative image of the susceptor 2. The imaging device 8 transmits the acquired comparative image to the control circuit 9.

In step S32, as illustrated in FIG. 15, the control circuit 9 controls the various parts or components of the film forming apparatus 100 to perform a colored film forming process to form a colored film 102 on the surface of the susceptor 2. The colored film forming process is performed in a state where the substrate W is not placed on the susceptor 2, for example. The colored film 102 is a silicon film, a silicon nitride film, a high dielectric constant (high-k) film, or a titanium nitride film, for example.

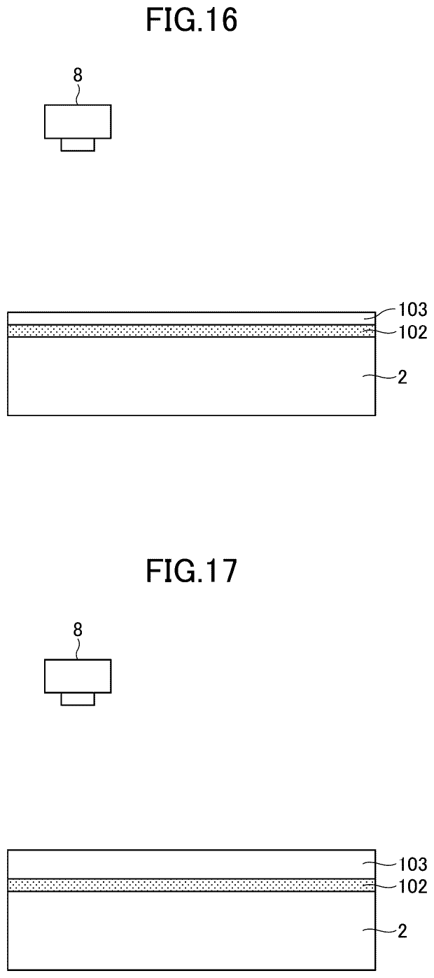

In step S33, the control circuit 9 controls the various parts or components of the film forming apparatus 100 to perform the film forming process. The film forming process is performed in a state where the substrate W is placed on the susceptor 2. When the film forming process is performed, as illustrated in FIG. 16, a film 103 is formed also on the colored film 102.

In step S34, the control circuit 9 determines whether or not to start the cleaning process. Whether or not to start the cleaning process is determined based on the number of cycles, duration, or the like of the film forming process performed (or the number of film forming cycles, film forming duration, or the like), with reference to a point in time when the cleaning process is performed, for example. When it is determined in step S34 that the cleaning process is to be started (YES in step S34), the control circuit 9 advances the process to step S35. On the other hand, when it is determined in step S34 that the cleaning process is not to be started (NO in step S34), the control circuit 9 returns the process to step S32. That is, the control circuit 9 controls the various parts or components of the film forming apparatus 100 so as to repeatedly perform the film forming process without performing the cleaning process until it is determined in step S34 to start the cleaning process. When the film forming process is repeatedly performed, as illustrated in FIG. 17, the thickness of the film 103 formed on the colored film 102 increases.

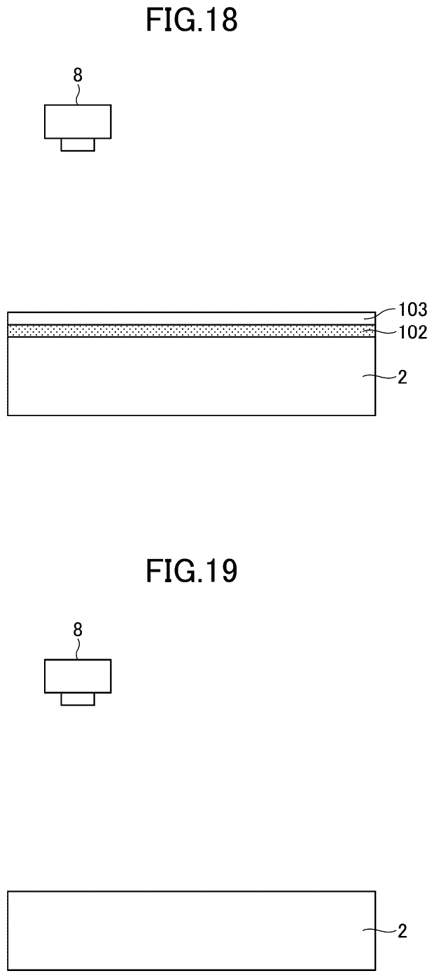

In step S35, the control circuit 9 controls the various parts or components of the film forming apparatus 100 to start the cleaning process. When the cleaning process is started, as illustrated in FIG. 18, the thickness of the film 103 formed on the colored film 102 gradually decreases.

In step S36, the imaging device 8 captures the image of the upper surface of the susceptor 2 during the cleaning process, and acquires the second determination image of the susceptor 2. The imaging device 8 transmits the acquired second determination image to the control circuit 9.

In step S37, the control circuit 9 calculates the difference between the color information at the predetermined position of the second determination image and the color information at the predetermined position of the comparative image. The difference becomes smaller as the thickness of the colored film 102 formed on the upper surface of the susceptor 2 decreases.

In step S38, the control circuit 9 determines whether or not to end the cleaning process based on the calculated difference. For example, in a case where the absolute value of the calculated difference becomes less than or equal to a preset threshold value, the control circuit 9 determines that the colored film 102 is removed, and determines to end the cleaning process. The threshold value is 0 (zero), for example. In a case where it is determined in step S38 that the cleaning process is to be ended (YES in step S38), the control circuit 9 advances the process to step S39. On the other hand, in a case where it is determined in step S38 that the cleaning process is not to be ended (NO in step S38), the control circuit 9 returns the process to step S36. That is, the control circuit 9 controls the various parts or components of the film forming apparatus 100 so as to continue the cleaning process until it is determined in step S38 that the cleaning process is to be ended.

In step S39, the control circuit 9 controls the various parts or components of the film forming apparatus 100 to end the cleaning process. Thus, as illustrated in FIG. 19, the colored film 102 and the film 103 formed on the upper surface of the susceptor 2 are removed.

In step S40, the control circuit 9 determines whether or not to attend to the maintenance of the film forming apparatus 100. Whether or not to attend to the maintenance of the film forming apparatus 100 is determined based on the number of cycles, duration, or the like of the cleaning process performed (or the number of cleaning cycles, cleaning duration, or the like), with reference to a point in time when the susceptor 2 is replaced, for example. In a case where it is determined in step S40 that the maintenance of the film forming apparatus 100 is to be performed (YES in step S40), the control circuit 9 ends the process illustrated in FIG. 13. In a case where it is determined in step S40 that the maintenance of the film forming apparatus 100 is not to be performed (NO in step S40), the control circuit 9 returns the process to step S32.

As described above, according to the determination method of the third example of the embodiment, the control circuit 9 calculates the difference between the color information at the predetermined position of the second determination image and the color information at the predetermined position of the comparative image, and determines the end timing of the cleaning process based on the calculated difference. In this case, it is possible to improve the accuracy of determining the end timing of the cleaning process.

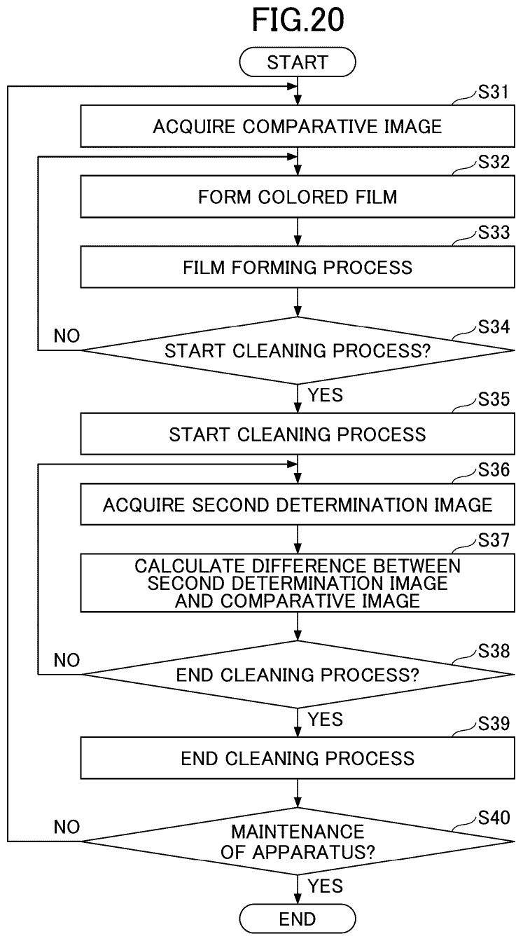

The determination method according to a fourth example of the embodiment will be described with reference to FIG. 20. The determination method according to the fourth example of the embodiment differs from the determination method according to the third example of the embodiment in that the imaging device 8 newly acquires a comparative image every time the cleaning process is performed. Otherwise, the determination method according to the fourth example of the embodiment points may be the same as the determination method according to the third example of the embodiment. FIG. 20 is a flow chart illustrating the determination method according to the fourth example of the embodiment.

As illustrated in FIG. 20, in the determination method according to the fourth example of the embodiment, in a case where it is determined in step S40 that the maintenance of the film forming apparatus 100 is not to be performed (NO in step S40), the control circuit 9 returns the process to step S31. That is, the imaging device 8 newly acquires a comparative image, and the control circuit 9 determines whether or not to end the cleaning process based on the difference between the color information of the second determination image and the color information of the comparative image newly received from the imaging device 8. In this case, even in a case where the surface state of the susceptor 2 varies due to the cleaning process, the newest comparative image can be used, so that the end timing of the cleaning process can be determined with a high accuracy.

In the embodiments, the case where the first information is the upper surface image of the susceptor acquired by the imaging device is described, but the present disclosure is not limited thereto. The first information may be information on various electromagnetic waves transmitted through or reflected by the susceptor.

In the embodiments, the case where the member disposed inside the vacuum chamber is the susceptor is described, but the present disclosure is not limited thereto. The member disposed inside the vacuum chamber may be various members formed of quartz, silicon, silicon carbide, or aluminum.

In the embodiments, the case where the film forming apparatus is a semi-batch type apparatus in which a plurality of substrates disposed on a susceptor inside a vacuum chamber are caused to revolve by the susceptor and the substrates are processed by sequentially passing the substrates through the adsorption region and the reaction region is described, but the present disclosure is not limited thereto. For example, the film forming apparatus may be a single-wafer type apparatus that processes substrates one by one, or a batch-type apparatus that simultaneously processes a plurality of substrates.

According to the present disclosure, it is possible to improve the accuracy for determining the timing of the cleaning process.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus configured to perform a film forming process to form a film inside a vacuum chamber and a cleaning process to remove the film formed inside the vacuum chamber, the film forming apparatus comprising:
the vacuum chamber;
a member disposed inside the vacuum chamber;
an acquisition device that acquires first information related to electromagnetic waves transmitted through or reflected by the member; and
a control circuit configured to perform a process including determining at least one of a start timing and an end timing of the cleaning process based on the first information acquired by the acquisition device.

2. The film forming apparatus as claimed in claim 1, wherein the first information is color information of the member.

3. The film forming apparatus as claimed in claim 2, wherein the color information is red, green, and blue (RGB) values or hue, saturation, and lightness (HSL) values.

4. The film forming apparatus as claimed in claim 1, wherein at least one of the start timing and the end timing is the end timing.

5. The film forming apparatus as claimed in claim 4, wherein the control circuit determines the end timing based on a difference between color information of the member while performing the cleaning process and color information of the member before forming the film thereon.

6. The film forming apparatus as claimed in claim 5, wherein the control circuit performs a control to end the cleaning process at the determined end timing.

7. The film forming apparatus as claimed in claim 1, wherein at least one of the start timing and the end timing is the start timing.

8. The film forming apparatus as claimed in claim 7, wherein the control circuit determines the start timing based on a difference between color information of the member during the film forming process or after performing the film forming process and color information of the member before forming the film thereon.

9. The film forming apparatus as claimed in claim 1, wherein:
the film is a transparent film or a white film, and
the control circuit performs a control to form a colored film on the surface of the member before the film forming process.

10. The film forming apparatus as claimed in claim 1, wherein the member is a susceptor on which a substrate is placed.

11. The film forming apparatus as claimed in claim 1, wherein the member is formed of quartz, silicon, silicon carbide, or aluminum.

12. A determination method in a film forming apparatus configured to perform a film forming process to form a film inside a vacuum chamber and a cleaning process to remove the film formed inside the vacuum chamber, the determination method comprising:
acquiring first information on electromagnetic waves transmitted through or reflected by a member disposed inside the vacuum chamber;
determining at least one of a start timing and an end timing of the cleaning process based on the first information.
